(19) United States
(12) Patent Application Publication
(10) Pub. No.: US 2026/0310099 A1
(43) Pub. Date: Oct. 8, 2026

(54) METHOD FOR SELECTING PATTERN REFERENCE FEATURES OF A SUBSTANTIALLY IRREGULAR PATTERN LAYOUT

(71) Applicant: ASML NETHERLANDS B.V., Veldhoven (NL)

(72) Inventors: Vahid BASTANI, Eindhoven (NL); Konstantin Sergeevich NECHAEV, Helmond (NL); Roy ANUNCIADO, Eindhoven (NL); Stefan Cornelis Theodorus VAN DER SANDEN, Mook (NL)

(73) Assignee: ASML NETHERLANDS B.V., Veldhoven (NL)

(21) Appl. No.: 19/485,797

(22) PCT Filed: May 13, 2024
(86) PCT No.: PCT/EP2024/063102

§ 371 Date: Nov. 19, 2025

(30) Foreign Application Priority Data
Jun. 12, 2023 (EP) 23178665.8

(51) Int. Cl. G03F 7/00

(52) U.S. Cl. CPC G03F 7/70508; G03F 7/705

(57) ABSTRACT

A method of selecting one or more reference features for characterizing a stochastic effect in a patterning process, the method including: obtaining a plurality of product features relating to a pattern for patterning on a substrate in the patterning process; obtaining product distribution data relating to one or more stochastic parameters characterizing a stochastic effect for the plurality of product features; selecting one or more reference features as a proper subset of the plurality of product features, wherein the one or more reference features are chosen to optimize estimation of the product distribution data from reference distribution data, the reference distribution data having been measured from the one or more reference features.

### CROSS-REFERENCE TO RELATED APPLICATIONS

This application claims priority of EP Application Serial No. 23178665.8 which was filed on 12 Jun. 2023, and which is incorporated herein in its entirety by reference.

### FIELD OF THE INVENTION

The present invention relates to methods and apparatus for applying patterns to a substrate in a lithographic process.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In order to monitor the lithographic process, parameters of the patterned substrate are measured. Parameters may include, for example, the overlay error between successive layers formed in or on the patterned substrate and critical linewidth or critical dimension (CD) of developed photosensitive resist. This measurement may be performed on a product substrate and/or on a dedicated metrology target. There are various techniques for making measurements of the microscopic structures formed in lithographic processes, including the use of scanning electron microscopes and various specialized tools.

An important metric in evaluating patterning performance is edge placement errors (EPE). The position of the edge of a feature is determined by the features lateral position (Overlay) and the size of the feature (CD). Part of this is very local and stochastic in nature; e.g., dependent on local overlay (LOVL) and local CD uniformity (LCDU). Also, Line Edge Roughness (LER) and line width roughness (LWR) may result in very local CD variations. All of these may be important contributors to the EPE performance.

EPE characterization and monitoring is very challenging for random logic layers due to the large pattern variation and low pattern repetition.

### SUMMARY OF THE INVENTION

It is an object of the invention to provide improved methods for stochastic metrology, and in particular for less repetitive or substantially irregular structures such as logic.

In a first aspect of the invention there is provided a method of selecting one or more reference features for characterizing a stochastic effect in a patterning process, the method comprising: obtaining a plurality of product features relating to a pattern for patterning on a substrate in the patterning process; obtaining product distribution data relating to one or more stochastic parameters characterizing the stochastic effect for said plurality of product features; and selecting one or more reference features as a proper subset of the plurality of product features, wherein the one or more reference features are chosen to optimize estimation of the product distribution data from reference distribution data, the reference distribution data having been measured from the one or more reference features.

In a second aspect of the invention there is provided a method of determining product distribution data relating to one or more stochastic parameters characterizing a stochastic effect, for a plurality of product features within a die area of a product pattern on a patterned substrate, the method comprising: obtaining reference distribution data relating to a measurement of a target comprising repetitions of reference features, said reference features comprising a proper subset of said plurality of product features, or representative features thereof; obtaining pre-calibrated relationship data which describes relationships between said product distribution data and said reference distribution data; and determining product distribution data for the plurality of product features from said reference distribution data and said pre-calibrated relationship data.

In a third aspect of the invention, there is provided a computing apparatus comprising a processor, and being configured to perform the method of the first or second aspect.

In a fourth aspect of the invention, there is provided a computer program comprising program instructions operable to perform the method of the first aspect or second aspect when run on a suitable apparatus.

Further aspects, features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

Embodiments of the invention will now be described, by way of example, with reference to the accompanying drawings in which:

FIG. 1 depicts a lithographic apparatus together with other apparatuses forming a production facility for semiconductor devices;

FIG. 2 schematically depicts two examples of stochastic variation: (a) line edge roughness LER; and (b) schematically line width roughness (LWR);

FIG. 3 is a flow diagram describing a first method according to an embodiment;

FIG. 4 is a flow diagram describing a second method according to an embodiment; and

FIG. 5 is an example of a target designed according to an embodiment.

### DETAILED DESCRIPTION

Before describing embodiments of the invention in detail, it is instructive to present an example environment in which embodiments of the present invention may be implemented.

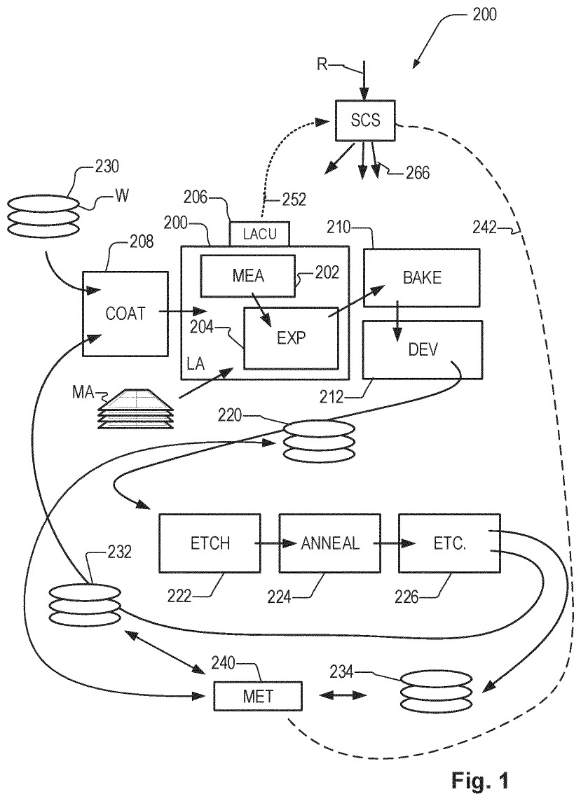

FIG. 1 at 200 shows a lithographic apparatus LA as part of an industrial production facility implementing a high-volume, lithographic manufacturing process. In the present example, the manufacturing process is adapted for the manufacture of for semiconductor products (integrated circuits) on substrates such as semiconductor wafers. The skilled person will appreciate that a wide variety of products can be manufactured by processing different types of substrates in variants of this process. The production of semiconductor products is used purely as an example which has great commercial significance today.

Within the lithographic apparatus (or “litho tool” 200 for short), a measurement station MEA is shown at 202 and an exposure station EXP is shown at 204. A control unit LACU is shown at 206. In this example, each substrate visits the measurement station and the exposure station to have a pattern applied. In an optical lithographic apparatus, for example, a projection system is used to transfer a product pattern from a patterning device MA onto the substrate using conditioned radiation and a projection system. This is done by forming an image of the pattern in a layer of radiation-sensitive resist material.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. The patterning MA device may be a mask or reticle, which imparts a pattern to a radiation beam transmitted or reflected by the patterning device. Well-known modes of operation include a stepping mode and a scanning mode. As is well known, the projection system may cooperate with support and positioning systems for the substrate and the patterning device in a variety of ways to apply a desired pattern to many target portions across a substrate. Programmable patterning devices may be used instead of reticles having a fixed pattern. The radiation for example may include electromagnetic radiation in the deep ultraviolet (DUV) or extreme ultraviolet (EUV) wavebands. The present disclosure is also applicable to other types of lithographic process, for example imprint lithography and direct writing lithography, for example by electron beam.

The lithographic apparatus control unit LACU which controls all the movements and measurements of various actuators and sensors to receive substrates W and reticles MA and to implement the patterning operations. LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus.

Before the pattern is applied to a substrate at the exposure station EXP, the substrate is processed in at the measurement station MEA so that various preparatory steps may be carried out. The preparatory steps may include mapping the surface height of the substrate using a level sensor and measuring the position of alignment marks on the substrate using an alignment sensor. The alignment marks are arranged nominally in a regular grid pattern. However, due to inaccuracies in creating the marks and also due to deformations of the substrate that occur throughout its processing, the marks deviate from the ideal grid. Consequently, in addition to measuring position and orientation of the substrate, the alignment sensor in practice must measure in detail the positions of many marks across the substrate area, if the apparatus is to print product features at the correct locations with very high accuracy. The apparatus may be of a so-called dual stage type which has two substrate tables, each with a positioning system controlled by the control unit LACU. While one substrate on one substrate table is being exposed at the exposure station EXP, another substrate can be loaded onto the other substrate table at the measurement station MEA so that various preparatory steps may be carried out. The measurement of alignment marks is therefore very time-consuming and the provision of two substrate tables enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations. Lithographic apparatus LA may for example is of a so-called dual stage type which has two substrate tables and two stations—an exposure station and a measurement station—between which the substrate tables can be exchanged.

Within the production facility, apparatus 200 forms part of a “litho cell” or “litho cluster” that contains also a coating apparatus 208 for applying photosensitive resist and other coatings to substrates W for patterning by the apparatus 200. At an output side of apparatus 200, a baking apparatus 210 and developing apparatus 212 are provided for developing the exposed pattern into a physical resist pattern. Between all of these apparatuses, substrate handling systems take care of supporting the substrates and transferring them from one piece of apparatus to the next. These apparatuses, which are often collectively referred to as the track, are under the control of a track control unit which is itself controlled by a supervisory control system SCS, which also controls the lithographic apparatus via lithographic apparatus control unit LACU. Thus, the different apparatus can be operated to maximize throughput and processing efficiency. Supervisory control system SCS receives recipe information R which provides in great detail a definition of the steps to be performed to create each patterned substrate.

Once the pattern has been applied and developed in the litho cell, patterned substrates 220 are transferred to other processing apparatuses such as are illustrated at 222, 224, 226. A wide range of processing steps is implemented by various apparatuses in a typical manufacturing facility. For the sake of example, apparatus 222 in this embodiment is an etching station, and apparatus 224 performs a post-etch annealing step. Further physical and/or chemical processing steps are applied in further apparatuses, 226, etc., Numerous types of operation can be required to make a real device, such as deposition of material, modification of surface material characteristics (oxidation, doping, ion implantation etc.), chemical-mechanical polishing (CMP), and so forth. The apparatus 226 may, in practice, represent a series of different processing steps performed in one or more apparatuses. As another example, apparatus and processing steps may be provided for the implementation of self-aligned multiple patterning, to produce multiple smaller features based on a precursor pattern laid down by the lithographic apparatus.

As is well known, the manufacture of semiconductor devices involves many repetitions of such processing, to build up device structures with appropriate materials and patterns, layer-by-layer on the substrate. Accordingly, substrates 230 arriving at the litho cluster may be newly prepared substrates, or they may be substrates that have been processed previously in this cluster or in another apparatus entirely. Similarly, depending on the required processing, substrates 232 on leaving apparatus 226 may be returned for a subsequent patterning operation in the same litho cluster, they may be destined for patterning operations in a different cluster, or they may be finished products to be sent for dicing and packaging.

Each layer of the product structure requires a different set of process steps, and the apparatuses 226 used at each layer may be completely different in type. Further, even where the processing steps to be applied by the apparatus 226 are nominally the same, in a large facility, there may be several supposedly identical machines working in parallel to perform the step 226 on different substrates. Small differences in set-up or faults between these machines can mean that they influence different substrates in different ways. Even steps that are relatively common to each layer, such as etching (apparatus 222) may be implemented by several etching apparatuses that are nominally identical but working in parallel to maximize throughput. In practice, moreover, different layers require different etch processes, for example chemical etches, plasma etches, according to the details of the material to be etched, and special requirements such as, for example, anisotropic etching.

The previous and/or subsequent processes may be performed in other lithography apparatuses, as just mentioned, and may even be performed in different types of lithography apparatus. For example, some layers in the device manufacturing process which are very demanding in parameters such as resolution and overlay may be performed in a more advanced lithography tool than other layers that are less demanding. Therefore some layers may be exposed in an immersion type lithography tool, while others are exposed in a ‘dry’ tool. Some layers may be exposed in a tool working at DUV wavelengths, while others are exposed using EUV wavelength radiation.

In order that the substrates that are exposed by the lithographic apparatus are exposed correctly and consistently, it is desirable to inspect exposed substrates to measure properties such as overlay errors between subsequent layers, line thicknesses, critical dimensions (CD), etc. Accordingly a manufacturing facility in which litho cell LC is located also includes metrology system which receives some or all of the substrates W that have been processed in the litho cell. Metrology results are provided directly or indirectly to the supervisory control system SCS. If errors are detected, adjustments may be made to exposures of subsequent substrates, especially if the metrology can be done soon and fast enough that other substrates of the same batch are still to be exposed. Also, already exposed substrates may be stripped and reworked to improve yield, or discarded, thereby avoiding performing further processing on substrates that are known to be faulty. In a case where only some target portions of a substrate are faulty, further exposures can be performed only on those target portions which are good.

Also shown in FIG. 1 is a metrology apparatus 240 which is provided for making measurements of parameters of the products at desired stages in the manufacturing process. A common example of a metrology station in a modern lithographic production facility is a scatterometer, for example a dark-field scatterometer, an angle-resolved scatterometer or a spectroscopic scatterometer, and it may be applied to measure properties of the developed substrates at 220 prior to etching in the apparatus 222. Using metrology apparatus 240, it may be determined, for example, that important performance parameters such as overlay or critical dimension (CD) do not meet specified accuracy requirements in the developed resist. Prior to the etching step, the opportunity exists to strip the developed resist and reprocess the substrates 220 through the litho cluster. The metrology results 242 from the apparatus 240 can be used to maintain accurate performance of the patterning operations in the litho cluster, by supervisory control system SCS and/or control unit LACU 206 making small adjustments over time, thereby minimizing the risk of products being made out-of-specification, and requiring re-work.

Another example of a metrology station is a scanning electron microscope (SEM), otherwise referred to as an electron beam (e-beam) metrology device, which may be included in addition to, or as an alternative to, a scatterometer. As such, metrology apparatus 240 may comprise an e-beam or SEM metrology device, either alone or in addition to a scatterometer. E-beam and SEM metrology devices have the advantage of measuring features directly (i.e., they directly image the features), rather than the indirect measurement techniques used in scatterometry (where parameter values are determined from reconstruction from and/or asymmetry in diffraction orders of radiation diffracted by the structure being measured). The main disadvantage with e-beam or SEM metrology devices is their measurement speed, which is much slower than scatterometry, limiting their potential application to specific offline monitoring processes.

Additionally, metrology apparatus 240 and/or other metrology apparatuses (not shown) can be applied to measure properties of the processed substrates 232, 234, and incoming substrates 230. The metrology apparatus can be used on the processed substrate to determine important parameters such as overlay or CD.

Lithographic projection apparatuses typically project a patterned (i.e., by a reticle) image at a point immediately above the substrate, and then ultimately into the resist. The projected image is called the aerial image, which comprises a distribution of light intensity as a function of spatial position in the image plane. The aerial image is the source of the information that is exposed into the resist, forming a gradient in dissolution rates that enables the three-dimensional resist image to appear during development.

Stochastic induced failure predictions are typically made based on one or more stochastic metrics. Such stochastic metrics may include stochastic measurements on the variation of one or more dimensional parameters; e.g. one or more of,: CD (so called Local CD Uniformity, LCDU), line edge position (so called line edge roughness LER), or linewidth (so called linewidth roughness LWR), for example. Accurate measurement of the number of failures is cumbersome, as low failure rates (e.g., of the order of 1 per million to 1 per billion) can be expected in an optimized process.

Imaging, using a lithographic projection apparatus, will result in a stochastic variation in one or more parameters, such as pronounced line width roughness (LWR) and local CD variation in small two-dimensional features such as holes. The stochastic variation may be attributed to factors such as photon shot noise, photon-generated secondary electrons, photon absorption variation, photon-generated acids in the resist. In the case of EUV lithography, the small sizes of features for which EUV is called for further compound this stochastic variation. The stochastic variation in smaller features are a significant factor in production yield and justifies inclusion in a variety of optimization processes of the lithographic projection apparatus.

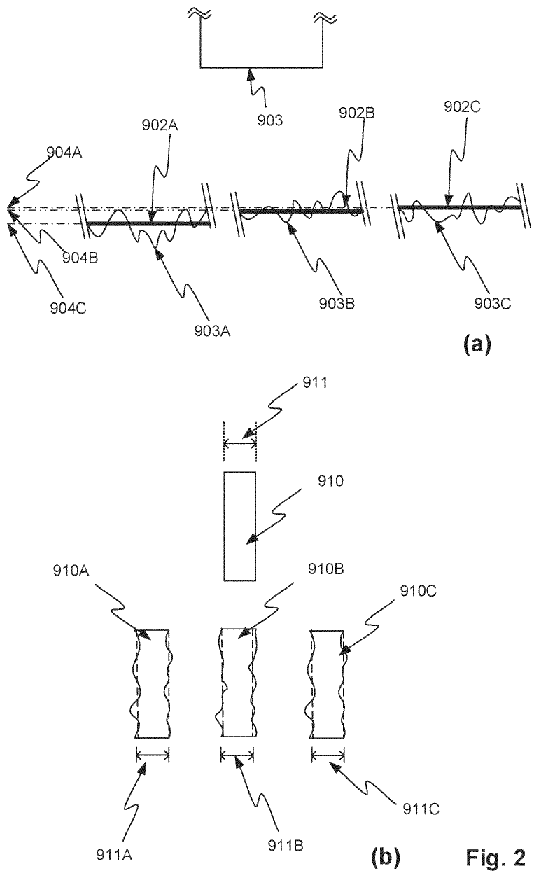

FIG. 2(a) schematically depicts a stochastic effect, line edge roughness LER. Assuming all conditions are identical in three exposures or simulations of exposure of an edge 903 of a feature on a design layout, the resist images 903A, 903B and 903C of the edge 903 may have slightly different shapes and locations. Locations 904A, 904B and 904C of the resist images 903 A, 903B and 903C may be measured by averaging the resist images to determine effective resist edges 902A, 902B and 902C, respectively. LER of the edge 903 may be a measure of the spatial distribution of the locations 904A, 904B and 904C. For example, the LER may be a 3σ of the spatial distribution (assuming the distribution is a normal distribution). The LER may be derived from many exposures or simulation of the edge 903.

FIG. 2(b) schematically depicts LWR. Assuming all conditions are identical in three exposures or simulations of exposure of a long rectangle feature 910 with a width 911 on a design layout, the resist images 910A, 910B and 910C of the rectangle feature 910 may have slightly different widths 911A, 911B and 911C, respectively. LWR of the rectangle feature 910 may be a measure of the distribution of the widths 911A, 911B and 911C. For example, the LWR may be a 3σ of the distribution (assuming the distribution is a normal distribution). The LWR may be derived from many exposures or simulation of the rectangle feature 910. In the context of a short feature (e.g., a contact hole), the widths of its images are not well defined because long edges are not available for averaging their locations. A similar quantity, LCDU, may be used to characterize the stochastic variation. The LCDU is a 3σ of the distribution (assuming the distribution is a normal distribution) of measured CDs of images of the short feature.

In order to monitor the patterning process (e.g., a device manufacturing process) that includes at least one pattern transfer step (e.g., an optical lithography step), the patterned substrate is inspected and one or more parameters of the patterned substrate are measured/determined. The one or more parameters may include, for example, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, placement error (e.g., edge placement error), etc. This measurement may be performed on a target of the product substrate itself and/or on a dedicated metrology target provided on the substrate. The measurement can be performed after-development of a resist but before etching or can be performed after-etch.

In an embodiment, a parameter obtained from a measurement process is a parameter derived from a parameter determined directly from the measurement process. As an example, a derived parameter obtained from a measurement parameter is edge placement error (EPE) for the patterning process. The edge placement error provides a variation in the location of an edge of a structure created by the patterning process. In an embodiment, the edge placement error is derived from an overlay value. In an embodiment, the edge placement error is derived from a combination of an overlay value and at least one stochastic metric. In an embodiment, the edge placement is derived from a combination of an overlay value, at least one CD stochastic metric value (e.g., CDU, LCDU) and (optionally) also another stochastic metric (e.g., edge roughness, shape asymmetry, etc. of the individual structures). In an embodiment, the edge placement error comprises an extreme value (e.g., 3 standard deviation, i.e., 3σ) of overlay and CD errors combined. In an embodiment, the edge placement error may comprise the following form, although other formulations are possible providing that at least the first two of the following terms are included:

$$\sqrt{{( 3 {σ}_{overlay} )}^{2} + {( \frac{3 {σ}_{CDU}}{2} )}^{2}} + \frac{3 {σ}_{OPE . PBA}}{2} + \frac{6 {σ}_{LER , LPE}}{\sqrt{2}}$$

wherein σ_{overlay} corresponds to the standard deviation of overlay, corresponds to the standard deviation of overlay, σ_{CDU} corresponds to the standard deviation of the critical dimension uniformity (CDU) of structures created in the patterning process, σ_{OPE.PBA} corresponds to the standard deviation of optical proximity effects (OPE) and/or proximity bias average (PBA) which is a difference between CD at pitch to a reference CD, and σ_{LER,LPE} corresponds to the standard deviation of line edge roughness (LER) and/or local placement error (LPE). While formulation above is in relation to standard deviation, it can be formulated in a different comparable statistical manner, such as variance. As such, the term edge placement error is not limited to any specific formulation, but is a general term relating to feature and/or edge position.

To summarize the above issues, because each instance of an image of a photolithography mask in resist is affected by stochastic shot-noise, a slightly different image will be obtained every time the mask is patterned on the wafer. This causes each instance of the feature in every die to have slightly different dimensions even under stable process and exposure conditions. This variation manifests itselfas a local variation (spatial scale <<1 mm) of edge placement related metrics (CD, overlay, etc.) which is associated with its corresponding local distribution, and can be defined for a number of stochastic metrics (metrics affected by stochastic effects) such as any CD metric (e.g., CD, CDU) and/or any placement error metric (e.g., LPE, EPE, LER) for example. To characterize the local distribution, SEM measurements of repeated instance imaging layout pattern may be performed.

A photolithography mask may comprise various types of layout patterns (features). Due to optical proximity and photoresists effects, each feature may have a different stochastic response resulting in a different local distribution of one or more stochastic metrics for every feature. Because of this, a prohibitively large amount of repeated SEM metrology is needed to characterize these distributions.

Some methods have been previously employed to address this issue. One such method comprises selecting (according to a suitable optimality criteria) a sub-area of the die to measure. Computational methods can then be used to calculate the distribution of the non-measured features from a limited number of measured features. However, SEM metrology is destructive to the photoresist and therefore in-die measurement may not be desirable (e.g. for high volume manufacturing (HVM) monitoring). It may also be difficult to find a sub-area of the die that allows sufficient computational reconstruction of all features.

Another presently used approach may comprise dividing the die features according to imaging behavior such that each group of features has a sufficiently similar behavior. An off-device (e.g., scribe-line) target can be designed which comprises representative features (e.g., a proper subset of features) from each respective group. The distribution of features for each respective group is assumed to be same as that determined for the representative features (as measured from the corresponding target) for that group. However, the number of groups can be large resulting in a large target. If too many groups are needed to characterize the entire population of features, the scribe-line target becomes impractically large. Also, the product feature behavior may vary substantially continuously (e.g., because of optical proximity correction), rendering grouping arbitrary or meaningless.

Instead of grouping product features, it is proposed to simulate stochastic behavior (e.g., distributions or local distributions of one or more stochastic metrics) of product features, for example using computational lithography techniques. Computational lithography is a known simulation technique which uses one or more models to simulate actual lithography processes and behavior. Such models may model different aspects of the lithography processes including, for example, inter alia: one or more of mask diffraction, optical imaging, resist development and/or an etch process. Computational lithography techniques (in the context of optical proximity control OPC) is described in “Full-Chip Lithography Simulation and Design Analysis—How OPC Is Changing IC Design,” C. Spence, Proc. SPIE, Vol. 5751, pp. 1-14 (2005) and “Exploring New High Speed, Mask Aware RET Verification Flows,” P. Martin et al., Proc. SPIE 5853, pp. 114-123, (2005)). These documents are incorporated herein by reference. Computational lithography techniques are well known and will not be described in detail herein. It can be appreciated that the concepts disclosed herein are not limited to using computational lithography; real measurements may be used on actual exposed substrates to obtain measured distribution data which can be used in place of or to supplement modeled distribution data. However, practical considerations will favor the use of using (at least mostly) modeled distribution data.

It is proposed that a (e.g., very small number) of basis features or reference features are defined which may comprise a (e.g., proper) subset and/or be representative of the product features, e.g., by analysis of variation of the simulated behaviors. Relationship data (e.g., functions) may be determined between product distribution parameter data (characterizing the distributions of the product features) and reference distribution parameter data (characterizing the distributions of the reference features) is determined. This relationship data enables prediction of product feature stochastics (e.g., distribution data for one or more stochastic metrics for all of the product features) based on an input of (e.g., measured) reference distribution data of the reference features. In this manner, metrology may be limited to the small number of reference features, with distribution data for all of the product features being determined based on this limited reference feature metrology. In an embodiment, the number of different reference features may be less than 10, less than 8, less than 6, less than 5, less than 4 or less than 3, for example.

As such, it is proposed that the relationship data will enable estimation of stochastics for a full set of product features based on reference metrology data from a target comprising as few reference features as possible. In a specific embodiment, the relationship data may describe linear relationships between reference distribution data and product distribution data.

The reference features may be comprised within a target, e.g., an off-product or scribe lane target for location in a scribe lane rather than within the die area. Such a target may be suitable for measurement using an SEM, for example. The target may comprise multiple repetitions (e.g., sufficient for stochastic analysis) of each of the reference features.

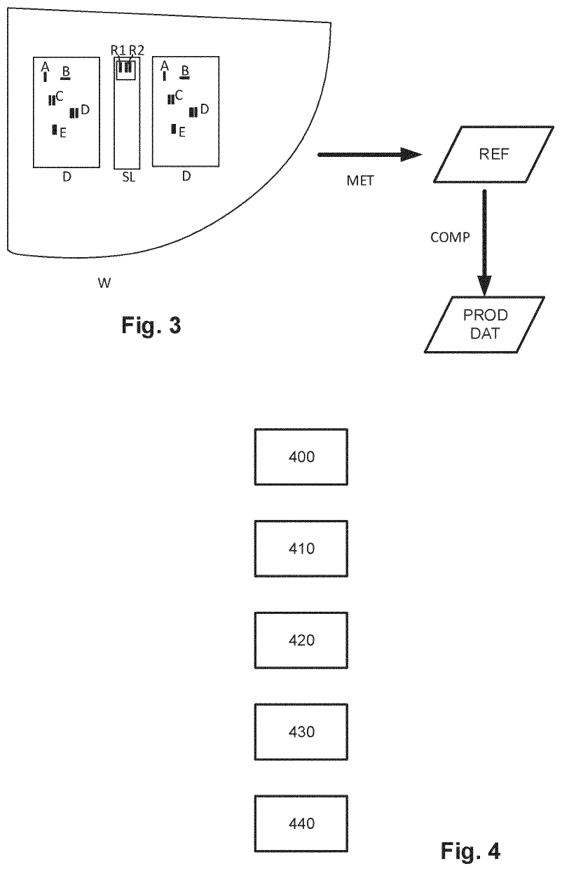

FIG. 3 is a flow diagram illustrating such a concept at a high level. Product features or in-die features A, B, C, D, E . . . (there will typically be a large number, particularly for logic dies for example) are comprised on a die D on a substrate W (shown in part). In a scribe lane SL, a target T is formed comprising in this example (multiple repetitions of) two reference features R1, R2. Metrology MET is performed on target T to obtain reference stochastic data or reference distribution data REF DAT. For example, the reference distribution data may comprise empirical distribution (e.g., a quantile function) Q(R1), Q(R2) of one or more stochastic metrics. After a processing or computation step COMP, estimated product distribution data PROD DAT may be determined from the reference distribution data REF DAT and a number of pre-calibrated relationships REL. For example, the distribution data Q(A), Q(B), Q(C) . . . for product feature A, B, C . . . Q(A) may be determined as:

$$Q ( A ) = f ( Q ( R 1 ) , Q ( R 2 ) ) = a 1 * Q ( R 1 ) + a 2 * Q ( R 2 )$$

$$Q ( B ) = f ( Q ( R 1 ) , Q ( R 2 ) ) = b 1 * Q ( R 1 ) + b 2 * Q ( R 2 )$$

$$…$$

where a1, a2, b1, b2 . . . are precalibrated model coefficients.

Also disclosed is are methods of determining the relationship data and determining the reference features from the product features; e.g., optimizing selection of a proper subset of the product features as reference features. This may be achieved by applying a suitable decomposition (e.g., singular value decomposition) on a matrix comprising (e.g., simulated) product distribution data, and determining a number of the lowest number singular vectors which sufficiently approximates the product distribution data (e.g., according to specification threshold). This number of singular vectors corresponds to the number of reference features (e.g., the number of reference features will be the number of singular vectors. The optimal set of reference features may be determined as those which maximize overall signal-to-noise ratio.

In this manner, the reference features may be selected from existing features on the mask (product features) using an optimization technique which provides best linear reconstruction of the product distribution data from measured reference distribution data.

FIG. 4 is a flow chart describing a method for defining a set of optimal reference features. At step 400, a stochastic simulation using computational lithography (e.g., specifically a lithography model and a resist model) may be employed to obtain simulated product distribution data (e.g. empirical quantile values). Optionally this simulated data may be supplemented (or even replaced) with equivalent measured data as measured from an exposed substrate. This may be done for all product features or a representative subset of the product features (e.g., EPE gauges), where the representative subset is desired to be in scope of the target B

At step 410, a matrix Q may be constructed, where each row is the product distribution parameters (e.g. quantile values) for the product features.

At step 420, a singular value decomposition Q=USV^{T} may be applied to matrix Q, and the first d number of singular vectors determined such that the error of the low-rank approximation \hat{Q}=

$${U}_{d} {S}_{d} {V}_{d}^{T}$$

is within a desired specification (e.g., as defined by an approximation error threshold T). For example, the error specification can be based on root-squared-error (Frobenius norm) ∥Q−\hat{Q}∥<T. Note that d will be number of reference features in the target.

At step 430, let i={i₁, . . . , i_{d}} be set of mutually different integers indicating subset of row indexes of matrix U, let U_{i,d} be a matrix formed by subset of first d columns and rows whose index are in set i and let Qᵢ be distribution parameters of subset of features in i. Then the low-rank reconstruction \tilde{Q} can optimally be calculated from Qᵢ as:

$$\tilde{Q} = {U}_{d} {U}_{i , d}^{+} {Q}_{i} \qquad EQ1$$

where

$${U}_{i , d}^{+}$$

is the pseudo inverse of U_{i,d}. Equation EQ1 is the computational model (where

$${U}_{d} {U}_{i , d}^{+}$$

is the relationship data) which can be used to calculate (estimated) product distribution data Q of all features using reference distribution data Qᵢ from the reference features.

At step 440, a set of optimal reference features is defined for the target based on a selection criterion (e.g., noise metric). Assuming noisy measurement, the optimal set of reference features that maximizes overall signal-to-noise ratio can be find by minimizing the reconstruction noise energy. This corresponds to solving the following optimization problem:

$${i}^{*} = {arg min}_{i} trace ( {( {U}_{i , d}^{T} {U}_{i , d} )}^{- 1} )$$

where i* is the optimized set of mutually different integers indicating a subset of row indexes of matrix U corresponding to the reference features.

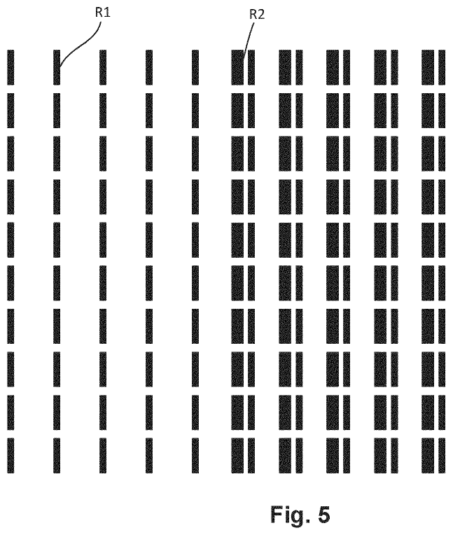

FIG. 5 is a purely exemplary target according to an embodiment, comprising multiple repetitions of first reference feature R1 and second reference feature R2. Reference features may for example be placed in a regular array in the target area, or their positioning can be further optimized to facilitate OPC. However, after such optimized positioning, the aerial image of the reference feature should match to that of the original product features of which they are copied.

The advantages of the proposed method is that this the size of the (e.g., SEM) target may be maintained small while having sufficient repetitions of the reference features for accurate determination of stochastic behavior. As such, the target may be made smaller then present, or maintained the same size in which case accuracy will be improved.

Further embodiments of the invention are disclosed in the list of numbered clauses below:
1. A method of selecting one or more reference features for characterizing a stochastic effect in a patterning process, the method comprising: obtaining a plurality of product features relating to a pattern for patterning on a substrate in the patterning process; obtaining product distribution data relating to one or more stochastic parameters subject to a stochastic effect for said plurality of product features; selecting one or more reference features as a proper subset of plurality of product features, wherein the one or more reference features are chosen to optimize estimation of the product distribution data from reference distribution data, the reference distribution data having been measured from the one or more reference features.
2. A method according to clause 1, wherein the one or more reference features are chosen to optimize linear reconstruction of the product distribution data from the reference distribution data.
3. A method according to clause 1 or 2, wherein said obtaining of the product distribution data comprises simulating said patterning process and determining simulated product distribution data from the simulated patterning process.
4. A method according to any preceding clause, comprising: performing a decomposition operation on said product distribution data, and determining an approximation of the product distribution data from a first one or more components of the decomposed product distribution data, wherein the number of said first one or more components comprised within the approximation is used to determine the number of reference features selected.
5. A method according to clause 4, wherein the number of reference features selected is equal to the number of said first one or more components.
6. A method according to clause 4 or 5, comprising determining the number of said first one or more components by determining whether said approximation is within a threshold for an approximation error.
7. A method according to any of clauses 4 to 6, comprising determining multiple subsets of said product distribution data, the multiple subsets comprising a number of elements corresponding to said number of reference features; and selecting an optimal subset from said multiple subsets based on a selection criterion.
8. A method according to clause 7, wherein the selection criterion is to select the subset which maximizes signal-to-noise ratio.
9. A method according to any of clauses 4 to 8, wherein the decomposition operation comprises a singular value decomposition and each said first one or more components comprises a singular vector.
10. A method according to clause 9, wherein the singular value decomposition is applied to said product distribution data represented within a matrix such that each row represents a different said product feature.
11. A method according to any of clauses 4 to 10, comprising determining relationship data which describes relationships between said product distribution data and said reference distribution data from the product of first one or more first components of said approximation and a pseudo inverse of first one or more first components corresponding to the reference features.
12. A method according to clause 11, wherein said one or more first components each comprise left singular vectors.
13. A method according to any preceding clause, wherein said one or more reference features number fewer than 10.
14. A method according to any preceding clause, wherein said one or more reference features number fewer than 5.
15. A method according to any preceding clause, wherein said one or more reference features number fewer than 3.
16. A method according to any preceding clause, wherein said distribution data comprises one or more local distributions of a stochastic metric.
17. A method according to clause 16, wherein the stochastic metric comprises a placement metric or critical dimension metric.
18. A method according to any preceding clause, comprising designing a target to comprise multiple repetitions of each said one or more reference features.
19. A method according to clause 18 wherein the target comprises dimensions suitable for accommodation in a scribe lane.
20. A method of determining product distribution data relating to one or more stochastic parameters characterizing a stochastic effect, for a plurality of product features within a die area of a product pattern on a patterned substrate, the method comprising: obtaining reference distribution data relating to a measurement of a target comprising repetitions of reference features, said reference features comprising a proper subset of said plurality of product features, or representative features thereof; obtaining pre-calibrated relationship data which describes relationships between said product distribution data and said reference distribution data; and determining product distribution data for the plurality of product features from said reference distribution data and said pre-calibrated relationship data.
21. A method according to clause 20, wherein the one or more reference features have been chosen to optimize linear reconstruction of the product distribution data from reference distribution data.
22. A method according to clause 20 or 21, wherein said one or more reference features number fewer than 10.
23. A method according to clause 20 or 21, wherein said one or more reference features number fewer than 5.
24. A method according to clause 20 or 21, wherein said one or more reference features number fewer than 3.
25. A method according to any of clauses 20 to 24, wherein said distribution data comprises one or more local distributions of a stochastic metric.
26. A method according to clause 25, wherein the stochastic metric comprises a placement metric or critical dimension metric.
27. A method according to any of clauses 20 to 26 comprising measuring a target comprising multiple repetitions of one or more reference features to obtain said reference distribution data.
28. A processing apparatus comprising a processor, and being configured to perform the method of any preceding clause.
29. A computer program comprising program instructions operable to perform the method of any of clauses 1 to 27, when run on a suitable apparatus.
30. A non-transient computer program carrier comprising the computer program of clause 29.
31. A metrology apparatus being operable to perform the method of any of clauses 20 to 27.

The terms “radiation” and “beam” used in relation to the lithographic apparatus encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A method of selecting one or more reference features for characterizing a stochastic effect in a patterning process, the method comprising:
obtaining a plurality of product features relating to a pattern for patterning on a substrate in the patterning process;
obtaining product distribution data relating to one or more stochastic parameters characterizing the stochastic effect for the plurality of product features; and
selecting, by a hardware computer system, one or more reference features as a proper subset of the plurality of product features, wherein the one or more reference features are chosen to optimize estimation of the product distribution data from reference distribution data, the reference distribution data having been measured from the one or more reference features.

2. The method as claimed in claim 1, wherein the one or more reference features are chosen to optimize linear reconstruction of the product distribution data from the reference distribution data.

3. The method as claimed in claim 1, wherein the obtaining product distribution data comprises simulating the patterning process and determining simulated product distribution data from the simulated patterning process.

4. The method as claimed in claim 1, further comprising:
performing a decomposition operation on the product distribution data, and
determining an approximation of the product distribution data from a first one or more components of the decomposed product distribution data, wherein the number of the first one or more components comprised within the approximation is used to determine the number of reference features selected.

5. The method as claimed in claim 4, wherein the number of reference features selected is equal to the number of the first one or more components.

6. The method as claimed in claim 4, further comprising determining the number of the first one or more components by determining whether the approximation is within a threshold of an approximation error.

7. The method as claimed in claim 4, further comprising;
determining multiple subsets of the product distribution data, the multiple subsets comprising a number of elements corresponding to the number of reference features; and
selecting an optimal subset from the multiple subsets based on a selection criterion.

8. The method as claimed in claim 7, wherein the selection criterion is to select the subset which maximizes a signal-to-noise ratio.

9. The method as claimed in claim 4, wherein the decomposition operation comprises a singular value decomposition and each first one or more components comprises a singular vector.

10. The method as claimed in claim 1, wherein the product distribution data comprises one or more local distributions of a stochastic metric.

11. The method as claimed in claim 10, wherein the stochastic metric comprises a placement metric or critical dimension metric.

12. The method as claimed in claim 1, further comprising designing a target comprising multiple repetitions of each one or more reference features.

13. A method of determining product distribution data relating to one or more stochastic parameters characterizing a stochastic effect, for a plurality of product features within a die area of a product pattern on a patterned substrate, the method comprising:
obtaining reference distribution data relating to a measurement of a target comprising repetitions of reference features, the reference features comprising a proper subset of the plurality of product features, or representative features thereof;
obtaining pre-calibrated relationship data which describes relationships between the product distribution data and the reference distribution data; and
determining, by a hardware computer system, product distribution data for the plurality of product features from the reference distribution data and the pre-calibrated relationship data.

14.-15. (canceled)

16. The method as claimed in claim 13, wherein the one or more reference features have been chosen to optimize linear reconstruction of the product distribution data from reference distribution data.

17. The method as claimed in claim 13, wherein the one or more reference features number fewer than 10.

18. The method as claimed in claim 13, wherein the distribution data comprises one or more local distributions of a stochastic metric.

19. The method as claimed in claim 18, wherein the stochastic metric comprises a placement metric or critical dimension metric.

20. The method as claimed in claim 13, comprising measuring a target comprising multiple repetitions of one or more reference features to obtain the reference distribution data.

21. A non-transitory computer-readable medium comprising instructions therein, the instructions, when executed by a computer system, configured to cause the computer system to perform at least the method as claimed in claim 13.

22. A non-transitory computer-readable medium comprising instructions therein, the instructions, when executed by a computer system, configured to cause the computer system to perform at least the method as claimed in claim 1.
